(19) United States
(12) Patent Application Publication
(10) Pub. No.: US 2025/0142911 A1
(43) Pub. Date: May 1, 2025

(54) MULTI-LAYERED EPITAXIAL STACK AND METHODS FOR PREPARING THE SAME

(71) Applicant: Applied Materials, Inc., Santa Clara, CA (US)

(72) Inventors: Arvind KUMAR, Santa Clara, CA (US); Roya BAGHI, Santa Clara, CA (US); Mahendra PAKALA, Santa Clara, CA (US); Thomas KIRSCHENHEITER, Tempe, AZ (US)

(21) Appl. No.: 18/889,143

(22) Filed: Sep. 18, 2024

Related U.S. Application Data
(60) Provisional application No. 63/545,911, filed on Oct. 26, 2023.

(51) Int. Cl. H01L 29/165; H01L 21/02; H01L 21/324

(52) U.S. Cl. CPC H10D 62/822; H01L 21/02532; H01L 21/0262; H01L 21/324

(57) ABSTRACT

Embodiments of the present disclosure generally relate to epitaxial film stacks and vapor deposition processes for preparing the epitaxial film stacks. In one or more embodiments, a carbon-doped silicon-germanium and silicon mini-stack is produced with relatively low defects or crystal imperfections. A multi-layered epitaxial stack containing a plurality of the carbon-doped silicon-germanium and silicon mini-stacks is deposited on a substrate. Each multi-layered epitaxial stack contains a carbon-doped silicon germanium stack and a silicon film. The carbon-doped silicon germanium stack contains a carbon-silicon-germanium layer disposed between a first silicon-germanium layer and a second silicon-germanium layer. The silicon film contains the silicon bulk layer disposed on the silicon seed layer. In some embodiments, a method for fabricating the epitaxial film stack includes sequentially depositing a carbon-doped silicon germanium stack and a silicon film to form the carbon-doped silicon-germanium and silicon mini-stack during a deposition cycle.

### CROSS-REFERENCE TO RELATED APPLICATIONS

This application claims benefit to U.S. Prov. Appl. No. 63/545,911, filed on Oct. 26, 2023, which is herein incorporated by reference in its entirety.

### BACKGROUND

### Field

Embodiments of the present disclosure generally relate to film stacks and vapor deposition, and more specifically, epitaxial film stacks and vapor deposition processes for preparing the epitaxial film stacks.

### Description of the Related Art

Microelectronic technology has advanced at a rapid pace and device dimensions have shrunk with advancing technology to provide faster processing and storage per unit space. As microelectronic technology advances, the market demands increasing smaller chips with increasingly more structures per unit area. One class of devices which has seen many advances in miniaturization are memory devices.

Two of the mainstays of the memory segment are NOT-AND (NAND) flash and dynamic random-access memory (DRAM), such as three-dimensional DRAM (3D-DRAM). DRAM is dynamic, volatile and very fast, making it well suited for short term system memory. DRAM has continued the path of scaling to smaller cell designs. This dimension shrink has driven the introduction of multiple patterning technology. Many of the DRAM devices contain epitaxial film stacks. Any crystal imperfections and/or defects cause leakage in the DRAM device and therefore a roadblock for the taller film stacks desired for 3D-DRAM over 2D-DRAM.

Therefore, a need exists for improved epitaxial film stacks and vapor deposition processes for preparing the epitaxial film stacks.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 depicts a workpiece containing a multi-layered epitaxial stack disposed on a substrate, according to one or more embodiments described and discussed herein.

FIG. 2 is a flowchart depicting a method for fabricating a multi-layered epitaxial stack, according to one or more embodiments described and discussed herein.

To facilitate understanding, identical reference numerals have been used, where possible, to designate identical elements that are common to the Figures. It is contemplated that elements and features of one or more embodiments may be beneficially incorporated in other embodiments.

### SUMMARY

Embodiments of the present disclosure generally relate to epitaxial film stacks and vapor deposition processes for preparing the epitaxial film stacks. In one or more embodiments, a carbon-doped silicon-germanium and silicon mini-stack is produced on a substrate. The carbon-doped silicon-germanium and silicon mini-stack has relatively low defects or crystal imperfections, such as a slipline count of less than 6,000 sliplines. The methods for epitaxial film stacks can be used throughout the microelectronics industry. The epitaxial film stacks can be or include a carbon-doped silicon-germanium and silicon mini-stack which can be utilized in a memory device. In one or more examples, the memory device is a three-dimensional, dynamic random access memory (3D-DRAM) device.

In one or more embodiments, workpiece is provided and contains a multi-layered epitaxial stack disposed on a substrate. The multi-layered epitaxial stack contains a plurality of carbon-doped silicon-germanium and silicon mini-stacks. Each multi-layered epitaxial stack contains a carbon-doped silicon germanium stack and a silicon film. The carbon-doped silicon germanium stack contains a carbon-silicon-germanium layer disposed between a first silicon-germanium layer and a second silicon-germanium layer. The silicon film contains the silicon bulk layer disposed on the silicon seed layer.

In other embodiments, a method of fabricating a film stack is provided and includes sequentially depositing a carbon-doped silicon germanium stack and a silicon film to form a carbon-doped silicon-germanium and silicon mini-stack disposed on a substrate during a deposition cycle. The method also includes repeating the deposition cycle to prepare a multi-layered epitaxial stack containing two or more of the carbon-doped silicon-germanium and silicon mini-stacks on the substrate. The deposition cycle contains exposing a workpiece containing the substrate to a first gas containing a silicon precursor, a silicon-chlorine precursor, a germanium precursor, and a carrier gas to deposit a first silicon-germanium layer, starting a flow of a silicon-carbon precursor, and exposing the workpiece to a second gas containing the silicon precursor, the silicon-chlorine precursor, the silicon-carbon precursor, the germanium precursor, and the carrier gas to deposit a carbon-silicon-germanium layer on the first silicon-germanium layer. The deposition cycle also contains ceasing the flow of the silicon-carbon precursor and exposing the workpiece to a third gas containing the silicon precursor, the silicon-chlorine precursor, the germanium precursor, and the carrier gas to deposit a second silicon-germanium layer on the carbon-silicon-germanium layer. The deposition cycle further contains ceasing a flow of the germanium precursor and exposing the workpiece to a fourth gas containing the silicon precursor, the silicon-chlorine precursor, and the carrier gas to deposit a silicon seed layer on the second silicon-germanium layer. The deposition cycle also contains ceasing a flow of the silicon-chlorine precursor and exposing the workpiece to a fifth gas containing the silicon precursor and the carrier gas to deposit a silicon bulk layer on the silicon seed layer.

In some embodiments, a method of fabricating a film stack is provided and includes sequentially depositing a carbon-doped silicon germanium stack and a silicon film to form a carbon-doped silicon-germanium and silicon mini-stack disposed on a substrate during a deposition cycle. The method also includes repeating the deposition cycle to prepare a multi-layered epitaxial stack containing two or more of the carbon-doped silicon-germanium and silicon mini-stacks on the substrate, where the deposition cycle is repeated from about 30 times to about times to prepare the multi-layered epitaxial stack. The method further includes exposing the workpiece containing the multi-layered epitaxial stack disposed on the substrate to an annealing process, where the annealing process is a furnace anneal process or a spike anneal process, and where the multi-layered epitaxial stack has a slipline count of about sliplines to about 5,000 sliplines after the annealing process.

### DETAILED DESCRIPTION

Embodiments of the present disclosure generally relate to epitaxial film stacks and vapor deposition processes for preparing the epitaxial film stacks. The epitaxial film stacks can be or include a carbon-doped silicon-germanium and silicon mini-stack produced on a substrate. The carbon-doped silicon-germanium and silicon mini-stack has relatively low defects or crystal imperfections, such as a slipline count of less than 6,000 sliplines, less than 3,000 sliplines, less than 2,000 sliplines, or even lower. The methods for depositing or otherwise preparing epitaxial film stacks can be utilized to produce epitaxial film stacks used throughout the microelectronics industry including as a memory device. In one or more examples, the memory device is a three-dimensional, dynamic random access memory (3D-DRAM) device.

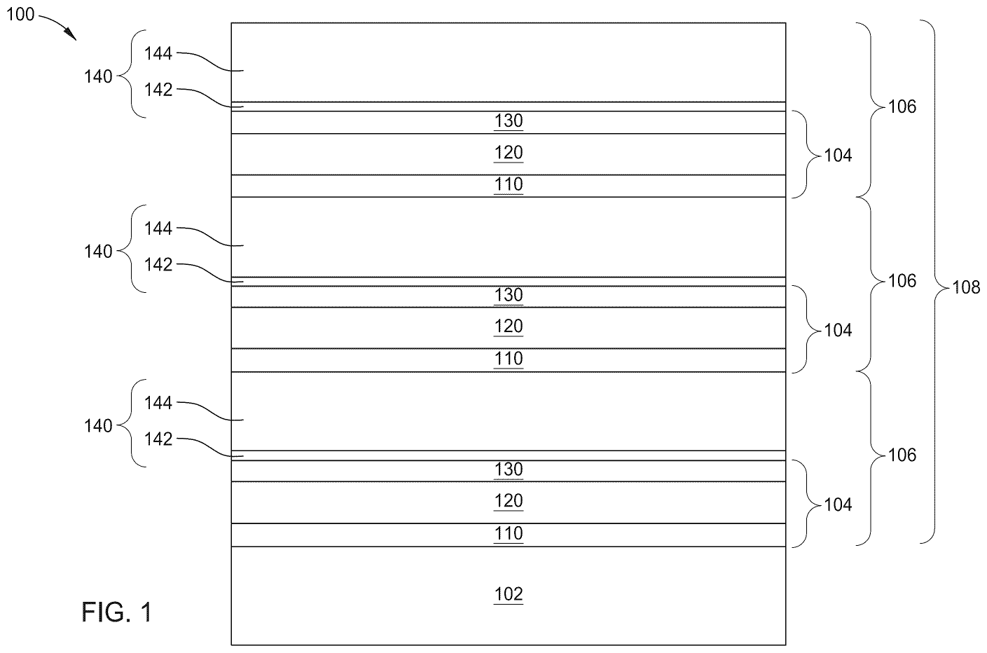

FIG. 1 depicts a workpiece 100 containing a multi-layered epitaxial stack 108 disposed on a substrate 102, according to one or more embodiments described and discussed herein. The multi-layered epitaxial stack 108 contains a plurality or two, three, or more of carbon-doped silicon-germanium and silicon mini-stacks 106. Each of the carbon-doped silicon-germanium and silicon mini-stacks 106 contains a carbon-doped silicon germanium stack 104 and a silicon film 140. Typically, the carbon-doped silicon germanium stack 104 is disposed on the silicon film 140, however their order can be reversed such that the silicon film 140 is disposed on the carbon-doped silicon germanium stack 104.

The carbon-doped silicon germanium stack 104 contains a carbon-silicon-germanium layer 120 disposed between a first silicon-germanium layer 110 and a second silicon-germanium layer 130. In some examples, the first silicon-germanium layer 110 and the second silicon-germanium layer 130 have the same composition, but in other example, the first silicon-germanium layer 110 and the second silicon-germanium layer 130 can have different compositions relative to each other.

The silicon film 140 contains the silicon bulk layer 144 disposed on the silicon seed layer 142. In some embodiments, the silicon seed layer 142 can be omitted and the silicon bulk layer 144 can be deposited directly on the second silicon-germanium layer 130. Each of the silicon seed layer 142 and the silicon bulk layer 144 can independently contain one or more silicon materials, such as epitaxial silicon, crystalline silicon, any dopant thereof, or any combination thereof.

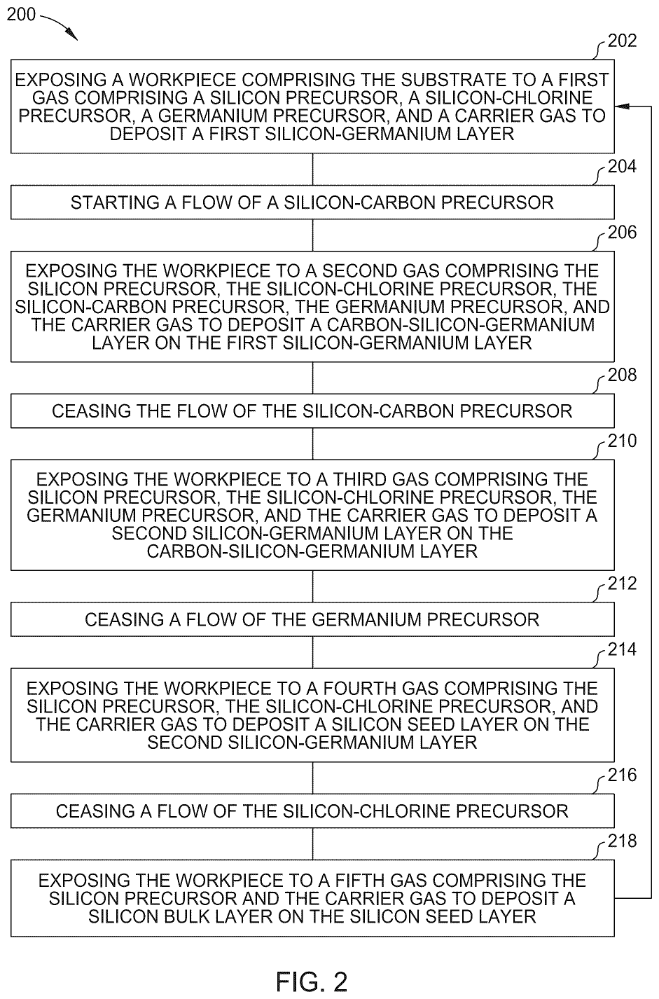

FIG. 2 is a flowchart depicting a process or method 200 for fabricating a multi-layered epitaxial stack, such as the multi-layered epitaxial stack 108 disposed on the substrate 102, according to one or more embodiments described and discussed herein. Other multi-layered epitaxial stacks and various film stacks can be deposited, fabricated, or otherwise produced by the method 200.

In one or more embodiments, the method 200 is provided and includes sequentially depositing a carbon-doped silicon germanium stack 104 and a silicon film 140 to form a carbon-doped silicon-germanium and silicon mini-stack disposed on a substrate 102 during a deposition cycle. The method 200 includes repeating the deposition cycle to prepare a multi-layered epitaxial stack 108 containing two or more of the carbon-doped silicon-germanium and silicon mini-stacks 106 on the substrate 102.

At operation 202 of the method 200, the deposition cycle includes exposing the workpiece 100 containing the substrate 102 to a first gas containing a silicon precursor, a silicon-chlorine precursor, a germanium precursor, and a carrier gas to deposit a first silicon-germanium layer 110. The silicon precursor can be or contain one or more of silane, disilane, trisilane, tetrasilane, or any combination thereof. The silicon-chlorine precursor can be or contain one or more of monochlorosilane, dichlorosilane, trichlorosilane, tetracholorosilane, hexachlorodisilane, or any combination thereof. The germanium precursor can be or contain one or more of germane, tetrachlorogermane, one or more organogermane compounds, or any combination thereof. The carrier gas can be or contain on or more of hydrogen (H₂), nitrogen (N₂), argon, helium, or any combination thereof. In some examples, the carrier gas contains a mixture of hydrogen and nitrogen. The mixture of hydrogen and nitrogen can have a hydrogen to nitrogen molar ratio in a range from about 1:10 to about 10:1, about 1:5 to about 5:1, about 1:3 to about 3:1, about 1:2 to about 2:1, or about 1:1.

At operation 204 of the method 200, the deposition cycle includes starting a flow of one or more silicon-carbon precursors. In one or more embodiments, the silicon-carbon precursor can be or contain one or more alkylsilanes. In some examples, the silicon-carbon precursor can be or contain methylsilane, dimethylsilane, or any combination thereof. The silicon-carbon precursor typically has silicon-carbon bonds which provides carbon to be incorporated into the carbon-silicon-germanium layers.

At operation 206 of the method 200, the deposition cycle includes exposing the workpiece 100 to a second gas containing the silicon precursor, the silicon-chlorine precursor, the silicon-carbon precursor, the germanium precursor, and the carrier gas to deposit a carbon-silicon-germanium layer 120 on the first silicon-germanium layer 110.

At operation 208 of the method 200, the deposition cycle includes ceasing the flow of the silicon-carbon precursor.

At operation 210 of the method 200, the deposition cycle includes exposing the workpiece 100 to a third gas containing the silicon precursor, the silicon-chlorine precursor, the germanium precursor, and the carrier gas to deposit a second silicon-germanium layer 130 on the carbon-silicon-germanium layer 120.

At operation 212 of the method 200, the deposition cycle includes ceasing a flow of the germanium precursor.

At operation 214 of the method 200, the deposition cycle includes exposing the workpiece 100 to a fourth gas containing the silicon precursor, the silicon-chlorine precursor, and the carrier gas to deposit a silicon seed layer 142 on the second silicon-germanium layer 130.

At operation 216 of the method 200, the deposition cycle includes ceasing a flow of the silicon-chlorine precursor.

At operation 218 of the method 200, the deposition cycle includes exposing the workpiece 100 to a fifth gas containing the silicon precursor and the carrier gas to deposit a silicon bulk layer 144 on the silicon seed layer 142.

Operations 202-218 can be repeated as many times as desired for preparing the multi-layered epitaxial stack 108 containing the desired number of the carbon-doped silicon-germanium and silicon mini-stacks 106 on the substrate 102. The deposition cycle is repeated in a range from about 1, 2, 3, 4, 5, 6, 8, 10, about 12, about 15, about 20, about 25, about 30, about 40, or about 50 times to about 60, about 70, about 80, about 90, about 100, about 120, about 140, about 150, about 160, about 180, about 200, about 250, or more times to prepare the multi-layered epitaxial stack 108. For example, the deposition cycle can be repeated from about 2 times to about 250 times, about 5 times to about 200 times, about 10 times to about 200 times, about 20 times to about 200 times, about 30 times to about 200 times, about 40 times to about 200 times, about 50 times to about 200 times, about 80 times to about 200 times, about 100 times to about 200 times, about 120 times to about 200 times, about 150 times to about 200 times, about 180 times to about 200 times, about 5 times to about 100 times, about 10 times to about 100 times, about 20 times to about 100 times, about 30 times to about 100 times, about 40 times to about 100 times, about 50 times to about 100 times, about 60 times to about 100 times, about 80 times to about 100 times, or about 90 times to about 100 times to prepare the multi-layered epitaxial stack 108.

In one or more examples, the deposition cycle, including operations 202-218, can be repeated from about 10 times to about 200 times to prepare the multi-layered epitaxial stack 108. In other examples, the deposition cycle can be repeated from about 30 times to about 100 times to prepare the multi-layered epitaxial stack 108. In some examples, the deposition cycle can be repeated from about 40 times to about 80 times to prepare the multi-layered epitaxial stack 108.

In one or more embodiments, after completing operations 202-218 of the method 200, additional processes can be conducted, although not depicted in FIG. 2. For example, the method can include further exposing the workpiece 100 containing the multi-layered epitaxial stack 108 disposed on the substrate 102 to one or more annealing processes. The annealing processes can be or include a furnace anneal process, a spike anneal process, a rapid thermal anneal process, or any combination thereof.

After the annealing process, the multi-layered epitaxial stack 108 can have a slipline count of less than 6,000 sliplines, less than 5,000 sliplines, less than 4,000 sliplines, less than 3,000 sliplines, less than 2,000 sliplines, or less than 1,000 sliplines. In some examples, the multi-layered epitaxial stack 108 can have a slipline count in a range from about 100 sliplines, about 200 sliplines, about 300 sliplines, about 400 sliplines, or about 500 sliplines to about 600 sliplines, about 700 sliplines, about 800 sliplines, about 900 sliplines, about or less than 1,000 sliplines, about or less than 2,000 sliplines, about or less than 3,000 sliplines, about or less than 4,000 sliplines, about or less than 5,000 sliplines, or about or less than 6,000 sliplines after the annealing process. For example, the multi-layered epitaxial stack 108 can have a slipline count of about 100 sliplines to about 5,000 sliplines, about 100 sliplines to about 4,000 sliplines, about 100 sliplines to about 3,000 sliplines, about 100 sliplines to about 2,000 sliplines, or about 100 sliplines to about 1,000 sliplines after the annealing process.

In one or more examples, the annealing process is a furnace anneal process. The workpiece 100 is heated to a temperature of about 500° C. to about 750° C. for a period of about 5 hours to about 20 hours during the furnace anneal process. The multi-layered epitaxial stack 108 has a slipline count of about 100 sliplines to about 2,000 sliplines after the furnace annealing process.

In other examples, the annealing process is a spike anneal process. The workpiece 100 is heated to a temperature of about 1,050° C. for a period of about 1 second to about 100 seconds during the spike anneal process. The multi-layered epitaxial stack 108 has a slipline count of less than 6,000 sliplines after the spike annealing process.

FIG. 1 depicts the workpiece 100 containing the carbon-doped silicon-germanium and silicon mini-stack 104 disposed on the substrate 102. The carbon-doped silicon-germanium and silicon mini-stack 104 can be a portion of a memory device. In one or more examples, the memory device is a 3D-DRAM (three-dimensional, dynamic random access memory) device.

The substrate 102 can be or include any suitable substrate material. In one or more embodiments, the substrate 102 contains one or more semiconductor materials and/or dopants, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), copper indium gallium selenide (CIGS), other semiconductor materials, dopants thereof, or any combination thereof. Although a few examples of materials from which the substrate 102 may be formed are described herein, any material that may serve as a foundation upon which passive and active electronic devices (e.g., memories, transistors, capacitors, inductors, resistors, switches, integrated circuits, amplifiers, optoelectronic devices, or any other electronic devices) may be fabricated is within the spirit and scope of the present disclosure. In one or more examples, the substrate 102 can be or contain silicon, a silicon germanium compound, a silicon germanium carbon compound, or any dopant thereof.

Each of the first silicon-germanium layer 110 and the second silicon-germanium layer 130 independently contains a silicon-germanium material which includes at least silicon and germanium. The silicon-germanium material can be doped or undoped. In one or more embodiments, each of the first silicon-germanium layer 110, the second silicon-germanium layer 130, and/or the silicon-germanium material independently contains a concentration of germanium in a range from about 5 atomic percent (at %), about 8 at %, about 10 at %, about 12 at %, about 15 at %, about 18 at %, or about 20 at % to about 22 at %, about 25 at %, about 28 at %, about 30 at %, about 32 at %, about 35 at %, about 38 at %, or about 40 at %. For example, each of the first silicon-germanium layer 110, the second silicon-germanium layer 130, and/or the silicon-germanium material independently contains about 5 at % to about 40 at %, about 5 at % to about 35 at %, about 5 at % to about 30 at %, about 5 at % to about 25 at %, about 5 at % to about 20 at %, about 5 at % to about 15 at %, about 5 at % to about 10 at %, about 10 at % to about 40 at %, about 10 at % to about 35 at %, about 10 at % to about 30 at %, about 10 at % to about 25 at %, about 10 at % to about 20 at %, about 10 at % to about 15 at %, about 10 at % to about 12 at %, about 15 at % to about 40 at %, about 15 at % to about 35 at %, about 15 at % to about 30 at %, about 15 at % to about 25 at %, about 15 at % to about 20 at %, about 15 at % to about 18 at % of germanium.

In some embodiments, each of the first silicon-germanium layer 110, the second silicon-germanium layer 130, and/or the silicon-germanium material independently contains a concentration of silicon in a range from about 60 at %, about 65 at %, about 70 at %, about 75 at %, about 78 at %, or about 80 at % to about 82 at %, about 85 at %, about 88 at %, about 90 at %, about 92 at %, or about 95 at %. For example, each of the first silicon-germanium layer 110, the second silicon-germanium layer 130, and/or the silicon-germanium material independently contains about 70 at % to about 95 at %, about 70 at % to about 90 at %, about 72 at % to about 90 at %, about 75 at % to about 90 at %, about 78 at % to about 90 at %, about 80 at % to about 90 at %, about 82 at % to about 90 at %, about 85 at % to about 90 at %, about 87 at % to about 90 at %, about 70 at % to about 85 at %, about 72 at % to about 85 at %, about 75 at % to about 85 at %, about 78 at % to about 85 at %, about 80 at % to about 85 at %, about 82 at % to about 85 at %, about 70 at % to about 80 at %, about 72 at % to about 80 at %, about 75 at % to about 80 at %, about 78 at % to about 80 at % of silicon.

In one or more examples, each of the first silicon-germanium layer 110, the second silicon-germanium layer 130, and/or the silicon-germanium material independently contains about 10 at % to about 30 at % of germanium and about 70 at % to about 90 at % of silicon. In other examples, each of the first silicon-germanium layer 110, the second silicon-germanium layer 130, and/or the silicon-germanium material independently contains about 15 at % to about 25 at % of germanium and about 75 at % to about 85 at % of silicon.

In one or more embodiments, each of the first silicon-germanium layer 110 and the second silicon-germanium layer 130 independently has a thickness in a range from about 0.5 nm, about 1 nm, about 2 nm, about 3 nm, about 4 nm, or about 5 nm to about 6 nm, about 7 nm, about 8 nm, about 9 nm, about 10 nm, about 12 nm, about 15 nm, or thicker. For example, each of the first silicon-germanium layer 110 and the second silicon-germanium layer 130 independently has a thickness of about 0.5 nm to about 15 nm, about 1 nm to about 10 nm, about 1 nm to about 8 nm, about 1 nm to about 8 nm, about 1 nm to about 5 nm, about 1 nm to about 4 nm, about 1 nm to about 3 nm, about 2 nm to about 10 nm, about 4 nm to about 10 nm, about 5 nm to about 10 nm, about 6 nm to about 10 nm, about 8 nm to about 10 nm, or about 10 nm to about 12 nm.

The carbon-silicon-germanium layer 120 contains carbon-silicon-germanium material which includes at least silicon, germanium, and carbon. The carbon-silicon-germanium material can be doped or undoped. In one or more embodiments, each of the carbon-silicon-germanium layer 120 and/or the carbon-silicon-germanium material independently contains a concentration of germanium in a range from about 5 at %, about 8 at %, about 10 at %, about 12 at %, about 15 at %, about 18 at %, or about 20 at % to about 22 at %, about 25 at %, about 28 at %, about 30 at %, about 32 at %, about 35 at %, about 38 at %, or about 40 at %. For example, each of the carbon-silicon-germanium layer 120 and/or the carbon-silicon-germanium material independently contains about 5 at % to about 40 at %, about 5 at % to about 35 at %, about 5 at % to about 30 at %, about 5 at % to about 25 at %, about 5 at % to about 20 at %, about 5 at % to about 15 at %, about 5 at % to about 10 at %, about 10 at % to about 40 at %, about 10 at % to about 35 at %, about 10 at % to about 30 at %, about 10 at % to about 25 at %, about 10 at % to about 20 at %, about 10 at % to about 15 at %, about 10 at % to about 12 at %, about 15 at % to about 40 at %, about 15 at % to about 35 at %, about 15 at % to about 30 at %, about 15 at % to about 25 at %, about 15 at % to about 20 at %, about 15 at % to about 18 at % of germanium.

Each of the carbon-silicon-germanium layer 120 and/or the carbon-silicon-germanium material independently contains a concentration of silicon in a range from about 60 at %, about 65 at %, about 70 at %, about 75 at %, about 78 at %, or about 80 at % to about 82 at %, about 85 at %, about 88 at %, about 90 at %, about 92 at %, or about 95 at %. For example, each of the carbon-silicon-germanium layer 120 and/or the carbon-silicon-germanium material independently contains about 70 at % to about 95 at %, about 70 at % to about 90 at %, about 72 at % to about 90 at %, about 75 at % to about 90 at %, about 78 at % to about 90 at %, about 80 at % to about 90 at %, about 82 at % to about 90 at %, about 85 at % to about 90 at %, about 87 at % to about 90 at %, about 70 at % to about 85 at %, about 72 at % to about 85 at %, about 75 at % to about 85 at %, about 78 at % to about 85 at %, about 80 at % to about 85 at %, about 82 at % to about 85 at %, about 70 at % to about 80 at %, about 72 at % to about 80 at %, about 75 at % to about 80 at %, about 78 at % to about 80 at % of silicon.

Each of the carbon-silicon-germanium layer 120 and/or the carbon-silicon-germanium material independently contains a concentration of carbon in a range from about 0.1 at %, about 0.2 at %, about 0.3 at %, about 0.4 at %, about 0.5 at %, about 0.6 at %, about 0.8 at %, or about 1 at % to about 1.2 at %, about 1.5 at %, about 1.8 at %, about 2 at %, about 2.2 at %, about 2.5 at %, about 2.8 at %, about 3 at %, about 3.5 at %, about 4 at %, about 4.5 at %, or about 5 at %. For example, each of the carbon-silicon-germanium layer 120 and/or the carbon-silicon-germanium material independently contains about 0.1 at % to about 5 at %, about 0.2 at % to about 5 at %, about 0.2 at % to about 4 at %, about 0.2 at % to about 3.5 at %, about 0.2 at % to about 3 at %, about 0.2 at % to about 2.5 at %, about 0.2 at % to about 2 at %, about 0.2 at % to about 1.8 at %, about 0.2 at % to about 1.5 at %, about 0.2 at % to about 1.2 at %, about 0.2 at % to about 1 at %, about 0.2 at % to about 0.8 at %, about 0.2 at % to about 0.5 at %, about 0.5 at % to about 5 at %, about 0.5 at % to about 4 at %, about 0.5 at % to about 3.5 at %, about 0.5 at % to about 3 at %, about 0.5 at % to about 2.5 at %, about 0.5 at % to about 2 at %, about 0.5 at % to about 1.8 at %, about 0.5 at % to about 1.5 at %, about 0.5 at % to about 1.2 at %, about 0.5 at % to about 1 at %, about 0.5 at % to about 0.8 at %, about 1 at % to about 5 at %, about 1 at % to about 4 at %, about 1 at % to about 3.5 at %, about 1 at % to about 3 at %, about 1 at % to about 2.5 at %, about 1 at % to about 2 at %, about 1 at % to about 1.8 at %, about 1 at % to about 1.5 at %, about 1 at % to about 1.2 at % of carbon.

In one or more examples, each of the carbon-silicon-germanium layer 120 and/or the carbon-silicon-germanium material independently contains about 70 at % to about 90 at % of silicon, about 10 at % to about 30 at % of germanium, and about 0.2 at % to about 3 at % of carbon. In some examples, each of the carbon-silicon-germanium layer 120 and/or the carbon-silicon-germanium material independently contains about 75 at % to about 85 at % of silicon, about 15 at % to about 25 at % of germanium, and about 0.5 at % to about 1.5 at % of carbon. In other examples, each of the carbon-silicon-germanium layer 120 and/or the carbon-silicon-germanium material independently contains about 78 at % to about 82 at % of silicon, about 18 at % to about 22 at % of germanium, and about 0.8 at % to about 1.2 at % of carbon.

In one or more embodiments, the carbon-silicon-germanium layer 120 has a thickness in a range from about 0.5 nm, about 1 nm, about 2 nm, about 3 nm, about 4 nm, about 5 nm, about 6 nm, about 8 nm, or about 10 nm to about 12 nm, about 14 nm, about 15 nm, about 16 nm, about 18 nm, about 20 nm, about 25 nm, or thicker. For example, each of the first silicon-germanium layer 110 and the second silicon-germanium layer 130 independently has a thickness of about 0.5 nm to about 25 nm, about 0.5 nm to about 20 nm, about 0.5 nm to about 15 nm, about 1 nm to about 25 nm, about 1 nm to about 20 nm, about 1 nm to about 15 nm, about 1 nm to about 10 nm, about 1 nm to about 8 nm, about 1 nm to about 8 nm, about 1 nm to about 5 nm, about 1 nm to about 4 nm, about 1 nm to about 3 nm, about 5 nm to about 25 nm, about 5 nm to about 20 nm, about 5 nm to about 15 nm, about 5 nm to about 10 nm, about 5 nm to about 8 nm, about 5 nm to about 8 nm, about 5 nm to about 7 nm, about 10 nm to about 25 nm, about 10 nm to about 20 nm, about 10 nm to about 15 nm, about 10 nm to about 12 nm, about 2 nm to about 10 nm, about 4 nm to about 10 nm, about 5 nm to about 10 nm, about 6 nm to about 10 nm, about 8 nm to about 10 nm, or about 10 nm to about 12 nm.

The carbon-doped silicon germanium stack 104 has a thickness in a range from about 1 nm, about 2 nm, about 3 nm, about 5 nm, about 6 nm, about 8 nm, or about 10 nm to about 12 nm, about 15 nm, about 18 nm, about 20 nm, about 25 nm, about 30 nm, about 40 nm, about 50 nm, or thicker. For example, the carbon-doped silicon germanium stack 104 has a thickness of about 1 nm to about 50 nm, about 5 nm to about 50 nm, about 5 nm to about 40 nm, about 5 nm to about 35 nm, about 5 nm to about 30 nm, about 5 nm to about 25 nm, about 5 nm to about 20 nm, about 5 nm to about 18 nm, about 5 nm to about 15 nm, about 5 nm to about 10 nm, about 5 nm to about 8 nm, about 10 nm to about 50 nm, about 10 nm to about 40 nm, about 10 nm to about 35 nm, about 10 nm to about 30 nm, about 10 nm to about 25 nm, about 10 nm to about 20 nm, about 10 nm to about 18 nm, about 10 nm to about 15 nm, about 10 nm to about 12 nm, about 15 nm to about 50 nm, about 15 nm to about 40 nm, about 15 nm to about 35 nm, about 15 nm to about 30 nm, about 15 nm to about 25 nm, about 15 nm to about 20 nm, or about 15 nm to about 18 nm.

The silicon seed layer 142 has a thickness in a range from about 0.05 nm, about 0.1 nm, about 0.2 nm, about 0.3 nm, about 0.4 nm, about 0.5 nm, about 0.6 nm, or to about 0.7 nm, about 0.8 nm, about 0.9 nm, about 1 nm, about 1.2 nm, about 1.5 nm, about 1.8 nm, about 2 nm, about 2.5 nm, about 3 nm, about 4 nm, about 5 nm, or thicker. For example, the silicon seed layer 142 has a thickness of about 0.05 nm to about 5 nm, about 0.05 nm to about 3 nm, about 0.05 nm to about 2 nm, about 0.05 nm to about 1 nm, about 0.05 nm to about 0.5 nm, about 0.1 nm to about 5 nm, about 0.1 nm to about 3 nm, about 0.1 nm to about 2 nm, about 0.1 nm to about 1 nm, about 0.1 nm to about 0.5 nm, about 0.5 nm to about 5 nm, about 0.5 nm to about 3 nm, about 0.5 nm to about 2 nm, about 0.5 nm to about 1 nm,

The silicon bulk layer 144 has a thickness in a range from about 1 nm, about 5 nm, about 10 nm, about 15 nm, about 20 nm, about 25 nm, about 30 nm, about 40 nm, or about 50 nm to about 60 nm, about 70 nm, about 80 nm, about 90 nm, about 100 nm, about 120 nm, about 135 nm, about 150 nm, about 180 nm, about 200 nm, or thicker. For example, the silicon bulk layer 144 has a thickness in a range from about 1 nm to about 200 nm, about 1 nm to about 150 nm, about 1 nm to about 120 nm, about 1 nm to about 100 nm, about 1 nm to about 80 nm, about 1 nm to about 60 nm, about 1 nm to about 50 nm, about 1 nm to about 40 nm, about 1 nm to about 30 nm, about 1 nm to about 20 nm, about 1 nm to about 10 nm, about 1 nm to about 5 nm, about 10 nm to about 200 nm, about 10 nm to about 150 nm, about 10 nm to about 120 nm, about 10 nm to about 100 nm, about 10 nm to about 80 nm, about 10 nm to about 60 nm, about 10 nm to about 50 nm, about 10 nm to about 40 nm, about 10 nm to about 30 nm, about 10 nm to about 20 nm, about 10 nm to about 15 nm, about 50 nm to about 200 nm, about 50 nm to about 150 nm, about 50 nm to about 120 nm, about 50 nm to about 100 nm, about 50 nm to about 80 nm, or about 50 nm to about 60 nm.

The silicon film 140 has a thickness in a range from about 1 nm, about 5 nm, about 10 nm, about 15 nm, about 20 nm, about 25 nm, about 30 nm, about 40 nm, or about 50 nm to about 60 nm, about 70 nm, about 80 nm, about 90 nm, about 100 nm, about 120 nm, about 135 nm, about 150 nm, about 180 nm, about 200 nm, or thicker. For example, the silicon film 140 has a thickness in a range from about 1 nm to about 200 nm, about 1 nm to about 150 nm, about 1 nm to about 120 nm, about 1 nm to about 100 nm, about 1 nm to about 80 nm, about 1 nm to about 60 nm, about 1 nm to about 50 nm, about 1 nm to about 40 nm, about 1 nm to about 30 nm, about 1 nm to about 20 nm, about 1 nm to about 10 nm, about 1 nm to about 5 nm, about 10 nm to about 200 nm, about 10 nm to about 150 nm, about 10 nm to about 120 nm, about 10 nm to about 100 nm, about 10 nm to about 80 nm, about 10 nm to about 60 nm, about 10 nm to about 50 nm, about 10 nm to about 40 nm, about 10 nm to about 30 nm, about 10 nm to about 20 nm, about 10 nm to about 15 nm, about 50 nm to about 200 nm, about 50 nm to about 150 nm, about 50 nm to about 120 nm, about 50 nm to about 100 nm, about 50 nm to about 80 nm, or about 50 nm to about 60 nm.

FIG. 1 depicts the multi-layered epitaxial stack 108 containing three the carbon-doped silicon-germanium and silicon mini-stacks 106 disposed on the substrate 102. However, the multi-layered epitaxial stack 108 may have a variety of different amounts of the carbon-doped silicon-germanium and silicon mini-stack 106 disposed on the substrate 102. The multi-layered epitaxial stack 108 may contain a range from 1 stack, 2 stacks, 3 stacks, 4 stacks, 5 stacks, 6 stacks, 7 stacks, 8 stacks, about 10 stacks, about 12 stacks, about 15 stacks, about 18 stacks, about 20 stacks, about 25 stacks, about 30 stacks, about 35 stacks, about 40 stacks, about 45 stacks, or about 50 stacks to about 55 stacks, about 60 stacks, about 70 stacks, about 80 stacks, about 90 stacks, about 100 stacks, about 110 stacks, about 120 stacks, about 130 stacks, about 140 stacks, about 150 stacks, about 160 stacks, about 170 stacks, about 180 stacks, about 190 stacks, about 200 stacks, about 220 stacks, about 250 stacks, about 300 stacks, or more of the carbon-doped silicon-germanium and silicon mini-stack 106. For example, the multi-layered epitaxial stack 108 may contain about 2 stacks to about 300 stacks, about 5 stacks to about 250 stacks, about 10 stacks to about 200 stacks, about 20 stacks to about 200 stacks, about 30 stacks to about 200 stacks, about 35 stacks to about 200 stacks, about 40 stacks to about 200 stacks, about 50 stacks to about 200 stacks, about 60 stacks to about 200 stacks, about 80 stacks to about 200 stacks, about 100 stacks to about 200 stacks, about 120 stacks to about 200 stacks, about 150 stacks to about 200 stacks, about 180 stacks to about 200 stacks, about 10 stacks to about 100 stacks, about 20 stacks to about 100 stacks, about 30 stacks to about 100 stacks, about 35 stacks to about 100 stacks, about 40 stacks to about 100 stacks, about 50 stacks to about 100 stacks, about 60 stacks to about 100 stacks, about 80 stacks to about 100 stacks, about 90 stacks to about 100 stacks, about 10 stacks to about 90 stacks, about 10 stacks to about 80 stacks, about 10 stacks to about 70 stacks, about 10 stacks to about 60 stacks, about 10 stacks to about 50 stacks, about 10 stacks to about 40 stacks, about 10 stacks to about 35 stacks, about 10 stacks to about 30 stacks, about 10 stacks to about 25 stacks, about 10 stacks to about 20 stacks, or about 10 stacks to about 15 stacks of the carbon-doped silicon-germanium and silicon mini-stack 106. In one or more examples, the multi-layered epitaxial stack 108 contains about 10 stacks to about 200 stacks of the plurality of carbon-doped silicon-germanium and silicon mini-stacks 106. In some examples, the multi-layered epitaxial stack 108 contains about 30 stacks to about 100 stacks of the plurality of carbon-doped silicon-germanium and silicon mini-stacks 106. In other examples, the multi-layered epitaxial stack 108 contains about 35 stacks to about 75 stacks of the plurality of carbon-doped silicon-germanium and silicon mini-stacks 106.

In some embodiments, a method of fabricating a film stack is provided and includes sequentially depositing a carbon-doped silicon germanium stack 104 and a silicon film 140 to form a carbon-doped silicon-germanium and silicon mini-stack disposed on a substrate 102 during a deposition cycle. The method also includes repeating the deposition cycle to prepare a multi-layered epitaxial stack 108 containing two or more of the carbon-doped silicon-germanium and silicon mini-stacks 106 on the substrate 102, where the deposition cycle is repeated from about 30 times to about 100 times to prepare the multi-layered epitaxial stack 108. The method further includes exposing the workpiece 100 containing the multi-layered epitaxial stack 108 disposed on the substrate 102 to an annealing process, where the annealing process is a furnace anneal process or a spike anneal process, and where the multi-layered epitaxial stack 108 has a slipline count of about 100 sliplines to about 5,000 sliplines. The deposition cycle contains exposing a workpiece 100 containing the substrate 102 to a first gas containing a silicon precursor, a silicon-chlorine precursor, a germanium precursor, and a carrier gas to deposit a first silicon-germanium layer 110, starting a flow of a silicon-carbon precursor, and exposing the workpiece 100 to a second gas containing the silicon precursor, the silicon-chlorine precursor, the silicon-carbon precursor, the germanium precursor, and the carrier gas to deposit a carbon-silicon-germanium layer 120 on the first silicon-germanium layer 110. The deposition cycle also contains ceasing the flow of the silicon-carbon precursor and exposing the workpiece 100 to a third gas containing the silicon precursor, the silicon-chlorine precursor, the germanium precursor, and the carrier gas to deposit a second silicon-germanium layer 130 on the carbon-silicon-germanium layer 120. The deposition cycle further contains ceasing a flow of the germanium precursor and exposing the workpiece 100 to a fourth gas containing the silicon precursor, the silicon-chlorine precursor, and the carrier gas to deposit a silicon seed layer 142 on the second silicon-germanium layer 130. The deposition cycle further contains ceasing a flow of the silicon-chlorine precursor and exposing the workpiece 100 to a fifth gas containing the silicon precursor and the carrier gas to deposit a silicon bulk layer 144 on the silicon seed layer 142.

Most traditional chemical vapor deposition (CVD) chambers or atomic layer deposition (ALD) chambers can be used as the processing chamber suitable for performing the vapor deposition processes described and discussed herein. An example of a tool or system that can benefit from the vapor deposition processes described and discussed herein is the Centura® system or Endura® system with an iSprint™ ALD/CVD SSW chamber, commercially available from Applied Materials, Inc.

Embodiments of the present disclosure further relate to any one or more of the following Examples 1-48:

1. A method of fabricating a film stack, comprising: sequentially depositing a carbon-doped silicon germanium stack and a silicon film to form a carbon-doped silicon-germanium and silicon mini-stack disposed on a substrate during a deposition cycle; and repeating the deposition cycle to prepare a multi-layered epitaxial stack comprising two or more of the carbon-doped silicon-germanium and silicon mini-stacks on the substrate, wherein the deposition cycle comprises: exposing a workpiece comprising the substrate to a first gas comprising a silicon precursor, a silicon-chlorine precursor, a germanium precursor, and a carrier gas to deposit a first silicon-germanium layer; starting a flow of a silicon-carbon precursor; exposing the workpiece to a second gas comprising the silicon precursor, the silicon-chlorine precursor, the silicon-carbon precursor, the germanium precursor, and the carrier gas to deposit a carbon-silicon-germanium layer on the first silicon-germanium layer; ceasing the flow of the silicon-carbon precursor; exposing the workpiece to a third gas comprising the silicon precursor, the silicon-chlorine precursor, the germanium precursor, and the carrier gas to deposit a second silicon-germanium layer on the carbon-silicon-germanium layer; ceasing a flow of the germanium precursor; exposing the workpiece to a fourth gas comprising the silicon precursor, the silicon-chlorine precursor, and the carrier gas to deposit a silicon seed layer on the second silicon-germanium layer; ceasing a flow of the silicon-chlorine precursor; and exposing the workpiece to a fifth gas comprising the silicon precursor and the carrier gas to deposit a silicon bulk layer on the silicon seed layer.

2. The method according to Example 1, wherein the multi-layered epitaxial stack has a slipline count of about 100 sliplines to about 5,000 sliplines.

3. The method according to Example 1 or 2, further comprising exposing the workpiece comprising the multi-layered epitaxial stack disposed on the substrate to an annealing process, wherein the multi-layered epitaxial stack has a slipline count of less than 5,000 sliplines after the annealing process.

4. The method according to Example 3, wherein: the annealing process is a furnace anneal process; the workpiece is heated to a temperature of about 500° C. to about 750° C. for a period of about 5 hours to about 20 hours during the furnace anneal process; and the multi-layered epitaxial stack has a slipline count of about 100 sliplines to about 2,000 sliplines after the furnace annealing process.

5. The method according to Example 3, wherein: the annealing process is a spike anneal process; the workpiece is heated to a temperature of about 1,050° C. for a period of about 1 second to about 100 seconds during the spike anneal process; and the multi-layered epitaxial stack has a slipline count of less than 6,000 sliplines after the spike annealing process.

6. The method according to any one of Examples 1-5, wherein the carbon-doped silicon germanium stack comprises the carbon-silicon-germanium layer disposed between the first silicon-germanium layer and the second silicon-germanium layer, and wherein the silicon film comprises the silicon bulk layer on the silicon seed layer.

7. The method according to any one of Examples 1-6, wherein the deposition cycle is repeated from about 10 times to about 200 times to prepare the multi-layered epitaxial stack.

8. The method according to any one of Examples 1-7, wherein the deposition cycle is repeated from about 30 times to about 100 times to prepare the multi-layered epitaxial stack.

9. The method according to any one of Examples 1-8, wherein the silicon precursor comprises silane, disilane, trisilane, tetrasilane, or any combination thereof.

10. The method according to any one of Examples 1-9, wherein the silicon-chlorine precursor comprises monochlorosilane, dichlorosilane, trichlorosilane, tetracholorosilane, hexachlorodisilane, or any combination thereof.

11. The method according to any one of Examples 1-10, wherein the silicon-carbon precursor comprises one or more alkylsilanes.

12. The method according to any one of Examples 1-11, wherein the silicon-carbon precursor comprises methylsilane, dimethylsilane, or any combination thereof.

13. The method according to any one of Examples 1-12, wherein the germanium precursor comprises germane.

14. The method according to any one of Examples 1-13, wherein the carrier gas comprises hydrogen (H₂), nitrogen (N₂), argon, helium, or any combination thereof.

15. The method according to any one of Examples 1-14, wherein the carrier gas comprises hydrogen (H₂) and nitrogen (N₂) having a hydrogen to nitrogen molar ratio in a range from about 1:10 to about 10:1.

16. The method according to any one of Examples 1-15, wherein the substrate comprises silicon, a silicon germanium compound, or a dopant thereof.

17. The method according to any one of Examples 1-16, wherein the carbon-doped silicon germanium stack has a thickness in a range from about 5 nm to about 20 nm.

18. The method according to any one of Examples 1-17, wherein each of the first silicon-germanium layer and the second silicon-germanium layer independently has a thickness in a range from about 1 nm to about 10 nm.

19. The method according to any one of Examples 1-18, wherein the carbon-silicon-germanium layer has a thickness in a range from about 1 nm to about 20 nm.

20. The method according to any one of Examples 1-19, wherein each of the first silicon-germanium layer and the second silicon-germanium layer independently comprises about 10 at % to about 30 at % of germanium and about 70 at % to about 90 at % of silicon.

21. The method according to any one of Examples 1-20, wherein the carbon-silicon-germanium layer comprises about 70 at % to about 90 at % of silicon, about 10 at % to about 30 at % of germanium, and about 0.2 at % to about 3 at % of carbon.

22. The method according to any one of Examples 1-21, wherein the silicon film has a thickness in a range from about 10 nm to about 150 nm.

23. The method according to any one of Examples 1-22, wherein the silicon seed layer has a thickness in a range from about 0.1 nm to about 1 nm.

24. The method according to any one of Examples 1-23, wherein the silicon bulk layer has a thickness in a range from about 10 nm to about 150 nm.

25. A method of fabricating a film stack, comprising: sequentially depositing a carbon-doped silicon germanium stack and a silicon film to form a carbon-doped silicon-germanium and silicon mini-stack disposed on a substrate during a deposition cycle; repeating the deposition cycle to prepare a multi-layered epitaxial stack comprising two or more of the carbon-doped silicon-germanium and silicon mini-stacks on the substrate, wherein the deposition cycle is repeated from about 30 times to about 100 times to prepare the multi-layered epitaxial stack, and wherein the deposition cycle comprises: exposing a workpiece comprising the substrate to a first gas comprising a silicon precursor, a silicon-chlorine precursor, a germanium precursor, and a carrier gas to deposit a first silicon-germanium layer; starting a flow of a silicon-carbon precursor; exposing the workpiece to a second gas comprising the silicon precursor, the silicon-chlorine precursor, the silicon-carbon precursor, the germanium precursor, and the carrier gas to deposit a carbon-silicon-germanium layer on the first silicon-germanium layer; ceasing the flow of the silicon-carbon precursor; exposing the workpiece to a third gas comprising the silicon precursor, the silicon-chlorine precursor, the germanium precursor, and the carrier gas to deposit a second silicon-germanium layer on the carbon-silicon-germanium layer; ceasing a flow of the germanium precursor; exposing the workpiece to a fourth gas comprising the silicon precursor, the silicon-chlorine precursor, and the carrier gas to deposit a silicon seed layer on the second silicon-germanium layer; ceasing a flow of the silicon-chlorine precursor; and exposing the workpiece to a fifth gas comprising the silicon precursor and the carrier gas to deposit a silicon bulk layer on the silicon seed layer; and exposing the workpiece comprising the multi-layered epitaxial stack disposed on the substrate to an annealing process, wherein the annealing process is a furnace anneal process or a spike anneal process, and wherein the multi-layered epitaxial stack has a slipline count of about 100 sliplines to about 5,000 sliplines.

26. The method according to Example 25, wherein: the annealing process is the furnace anneal process; the workpiece is heated to a temperature of about 500° C. to about 750° C. for a period of about 5 hours to about 20 hours during the furnace anneal process; and the multi-layered epitaxial stack has a slipline count of about 100 sliplines to about 2,000 sliplines after the furnace annealing process.

27. The method according to Example 25 or 26, wherein: the annealing process is the spike anneal process; the workpiece is heated to a temperature of about 1,050° C. for a period of about 1 second to about 100 seconds during the spike anneal process; and the multi-layered epitaxial stack has a slipline count of less than 6,000 sliplines after the spike annealing process.

28. The method according to any one of Examples 25-27, wherein each of the first silicon-germanium layer and the second silicon-germanium layer independently comprises about 10 at % to about 30 at % of germanium and about 70 at % to about 90 at % of silicon.

29. The method according to any one of Examples 25-28, wherein the carbon-silicon-germanium layer comprises about 70 at % to about 90 at % of silicon, about 10 at % to about 30 at % of germanium, and about 0.2 at % to about 3 at % of carbon.

30. A workpiece, comprising: a multi-layered epitaxial stack disposed on a substrate, wherein: the multi-layered epitaxial stack comprises a plurality of carbon-doped silicon-germanium and silicon mini-stacks; each of the carbon-doped silicon-germanium and silicon mini-stacks comprises a carbon-doped silicon germanium stack and a silicon film; the carbon-doped silicon germanium stack comprises a carbon-silicon-germanium layer disposed between a first silicon-germanium layer and a second silicon-germanium layer; and the silicon film comprises the silicon bulk layer disposed on the silicon seed layer.

31. The workpiece according to Example 30, wherein the multi-layered epitaxial stack has a slipline count of less than 6,000 sliplines.

32. The workpiece according to Example 30 or 31, wherein the multi-layered epitaxial stack has a slipline count of about 100 sliplines to about 5,000 sliplines.

33. The workpiece according to any one of Examples 30-32, wherein the multi-layered epitaxial stack has a slipline count of about 100 sliplines to about 2,000 sliplines.

34. The workpiece according to any one of Examples 30-33, wherein the carbon-doped silicon germanium stack comprises the carbon-silicon-germanium layer disposed between the first silicon-germanium layer and the second silicon-germanium layer, and wherein the silicon film comprises the silicon bulk layer on the silicon seed layer.

35. The workpiece according to any one of Examples 30-34, wherein the multi-layered epitaxial stack contains a plurality of carbon-doped silicon-germanium and silicon mini-stacks containing about 10 stacks to about 200 stacks.

36. The workpiece according to any one of Examples 30-35, wherein the multi-layered epitaxial stack contains a plurality of carbon-doped silicon-germanium and silicon mini-stacks containing about 30 stacks to about 100 stacks.

37. The workpiece according to any one of Examples 30-36, wherein the substrate comprises silicon, a silicon germanium compound, or a dopant thereof.

38. The workpiece according to any one of Examples 30-37, wherein the carbon-doped silicon germanium stack has a thickness in a range from about 5 nm to about 20 nm.

39. The workpiece according to any one of Examples 30-38, wherein each of the first silicon-germanium layer and the second silicon-germanium layer independently has a thickness in a range from about 1 nm to about 10 nm.

40. The workpiece according to any one of Examples 30-39, wherein the carbon-silicon-germanium layer has a thickness in a range from about 1 nm to about 20 nm.

41. The workpiece according to any one of Examples 30-40, wherein each of the first silicon-germanium layer and the second silicon-germanium layer independently comprises about 10 at % to about 30 at % of germanium and about 70 at % to about 90 at % of silicon.

42. The workpiece according to any one of Examples 30-41, wherein the carbon-silicon-germanium layer comprises about 70 at % to about 90 at % of silicon, about 10 at % to about 30 at % of germanium, and about 0.2 at % to about 3 at % of carbon.

43. The workpiece according to any one of Examples 30-42, wherein the silicon film has a thickness in a range from about 10 nm to about 150 nm.

44. The workpiece according to any one of Examples 30-43, wherein the silicon seed layer has a thickness in a range from about 0.1 nm to about 1 nm.

45. The workpiece according to any one of Examples 30-44, wherein the silicon bulk layer has a thickness in a range from about 10 nm to about 150 nm.

46. The workpiece according to any one of Examples 30-45, wherein the carbon-doped silicon-germanium and silicon mini-stack is a portion of a memory device.

47. The workpiece according to Example 46, wherein the memory device is a 3D-DRAM (three-dimensional, dynamic random access memory) device.

48. A workpiece, a multi-layered epitaxial stack, or a composition fabricated or made by the method according to any one of Examples 1-29.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation can be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A method of fabricating a film stack, comprising:
sequentially depositing a carbon-doped silicon germanium stack and a silicon film to form a carbon-doped silicon-germanium and silicon mini-stack disposed on a substrate during a deposition cycle; and
repeating the deposition cycle to prepare a multi-layered epitaxial stack comprising two or more of the carbon-doped silicon-germanium and silicon mini-stacks on the substrate, wherein the deposition cycle comprises:
exposing a workpiece comprising the substrate to a first gas comprising a silicon precursor, a silicon-chlorine precursor, a germanium precursor, and a carrier gas to deposit a first silicon-germanium layer;
starting a flow of a silicon-carbon precursor;
exposing the workpiece to a second gas comprising the silicon precursor, the silicon-chlorine precursor, the silicon-carbon precursor, the germanium precursor, and the carrier gas to deposit a carbon-silicon-germanium layer on the first silicon-germanium layer;
ceasing the flow of the silicon-carbon precursor;
exposing the workpiece to a third gas comprising the silicon precursor, the silicon-chlorine precursor, the germanium precursor, and the carrier gas to deposit a second silicon-germanium layer on the carbon-silicon-germanium layer;
ceasing a flow of the germanium precursor;
exposing the workpiece to a fourth gas comprising the silicon precursor, the silicon-chlorine precursor, and the carrier gas to deposit a silicon seed layer on the second silicon-germanium layer;
ceasing a flow of the silicon-chlorine precursor; and
exposing the workpiece to a fifth gas comprising the silicon precursor and the carrier gas to deposit a silicon bulk layer on the silicon seed layer.

2. The method of claim 1, wherein the multi-layered epitaxial stack has a slipline count of about 100 sliplines to about 5,000 sliplines.

3. The method of claim 1, further comprising exposing the workpiece comprising the multi-layered epitaxial stack disposed on the substrate to an annealing process, wherein the multi-layered epitaxial stack has a slipline count of less than 5,000 sliplines after the annealing process.

4. The method of claim 3, wherein:
the annealing process is a furnace anneal process;
the workpiece is heated to a temperature of about 500° C. to about 750° C. for a period of about 5 hours to about 20 hours during the furnace anneal process; and
the multi-layered epitaxial stack has a slipline count of about 100 sliplines to about 2,000 sliplines after the furnace annealing process.

5. The method of claim 3, wherein:
the annealing process is a spike anneal process;
the workpiece is heated to a temperature of about 1,050° C. for a period of about 1 second to about 100 seconds during the spike anneal process; and
the multi-layered epitaxial stack has a slipline count of less than 6,000 sliplines after the spike annealing process.

6. The method of claim 1, wherein the carbon-doped silicon germanium stack comprises the carbon-silicon-germanium layer disposed between the first silicon-germanium layer and the second silicon-germanium layer, and wherein the silicon film comprises the silicon bulk layer on the silicon seed layer.

7. The method of claim 1, wherein the deposition cycle is repeated from about 10 times to about 200 times to prepare the multi-layered epitaxial stack.

8. The method of claim 1, wherein the deposition cycle is repeated from about 30 times to about 100 times to prepare the multi-layered epitaxial stack.

9. The method of claim 1, wherein the silicon precursor comprises silane, disilane, trisilane, tetrasilane, or any combination thereof, and wherein the silicon-chlorine precursor comprises monochlorosilane, dichlorosilane, trichlorosilane, tetracholorosilane, hexachlorodisilane, or any combination thereof.

10. The method of claim 1, wherein the silicon-carbon precursor comprises one or more alkylsilanes.

11. The method of claim 1, wherein the silicon-carbon precursor comprises methylsilane, dimethylsilane, or any combination thereof.

12. The method of claim 1, wherein the germanium precursor comprises germane, and wherein the carrier gas comprises hydrogen (H₂), nitrogen (N₂), argon, helium, or any combination thereof.

13. The method of claim 1, wherein the carrier gas comprises hydrogen (H₂) and nitrogen (N₂) having a hydrogen to nitrogen molar ratio in a range from about 1:10 to about 10:1.

14. The method of claim 1, wherein the carbon-doped silicon germanium stack has a thickness in a range from about 5 nm to about 20 nm.

15. The method of claim 1, wherein each of the first silicon-germanium layer and the second silicon-germanium layer independently has a thickness in a range from about 1 nm to about 10 nm, and wherein the carbon-silicon-germanium layer has a thickness in a range from about 1 nm to about 20 nm.

16. The method of claim 1, wherein each of the first silicon-germanium layer and the second silicon-germanium layer independently comprises about 10 at % to about 30 at % of germanium and about 70 at % to about 90 at % of silicon.

17. The method of claim 1, wherein the carbon-silicon-germanium layer comprises about 70 at % to about 90 at % of silicon, about 10 at % to about 30 at % of germanium, and about 0.2 at % to about 3 at % of carbon.

18. The method of claim 1, wherein the silicon film has a thickness in a range from about 10 nm to about 150 nm, wherein the silicon seed layer has a thickness in a range from about 0.1 nm to about 1 nm, and wherein the silicon bulk layer has a thickness in a range from about 10 nm to about 150 nm.

19. A method of fabricating a film stack, comprising:
sequentially depositing a carbon-doped silicon germanium stack and a silicon film to form a carbon-doped silicon-germanium and silicon mini-stack disposed on a substrate during a deposition cycle;
repeating the deposition cycle to prepare a multi-layered epitaxial stack comprising two or more of the carbon-doped silicon-germanium and silicon mini-stacks on the substrate, wherein the deposition cycle is repeated from about 30 times to about 100 times to prepare the multi-layered epitaxial stack, and wherein the deposition cycle comprises:
exposing a workpiece comprising the substrate to a first gas comprising a silicon precursor, a silicon-chlorine precursor, a germanium precursor, and a carrier gas to deposit a first silicon-germanium layer;
starting a flow of a silicon-carbon precursor;
exposing the workpiece to a second gas comprising the silicon precursor, the silicon-chlorine precursor, the silicon-carbon precursor, the germanium precursor, and the carrier gas to deposit a carbon-silicon-germanium layer on the first silicon-germanium layer;
ceasing the flow of the silicon-carbon precursor;
exposing the workpiece to a third gas comprising the silicon precursor, the silicon-chlorine precursor, the germanium precursor, and the carrier gas to deposit a second silicon-germanium layer on the carbon-silicon-germanium layer;
ceasing a flow of the germanium precursor;
exposing the workpiece to a fourth gas comprising the silicon precursor, the silicon-chlorine precursor, and the carrier gas to deposit a silicon seed layer on the second silicon-germanium layer;
ceasing a flow of the silicon-chlorine precursor; and
exposing the workpiece to a fifth gas comprising the silicon precursor and the carrier gas to deposit a silicon bulk layer on the silicon seed layer; and
exposing the workpiece comprising the multi-layered epitaxial stack disposed on the substrate to an annealing process, wherein the annealing process is a furnace anneal process or a spike anneal process, and wherein the multi-layered epitaxial stack has a slipline count of about 100 sliplines to about 5,000 sliplines.

20. A workpiece, comprising:
a multi-layered epitaxial stack disposed on a substrate, wherein:
the multi-layered epitaxial stack has a slipline count of less than 6,000 sliplines;
the multi-layered epitaxial stack comprises a plurality of carbon-doped silicon-germanium and silicon mini-stacks;
each of the carbon-doped silicon-germanium and silicon mini-stacks comprises a carbon-doped silicon germanium stack and a silicon film;
the carbon-doped silicon germanium stack comprises a carbon-silicon-germanium layer disposed between a first silicon-germanium layer and a second silicon-germanium layer; and
the silicon film comprises the silicon bulk layer disposed on the silicon seed layer.
